(19) United States
(12) Patent Application Publication
(10) Pub. No.: US 2012/0015507 A1
(43) Pub. Date: Jan. 19, 2012

(54) PLASMA DOPING APPARATUS AND PLASMA DOPING METHOD

(75) Inventors: Masaru Tanaka, Yokosuka-shi (JP); Masashi Kuriyama, Yokosuka-shi (JP); Hiroki Murooka, Ehime (JP)

(73) Assignees: SEN CORPORATION, Tokyo (JP); SUMITOMO HEAVY INDUSTRIES, LTD., Tokyo (JP)

(21) Appl. No.: 13/183,938

(22) Filed: Jul. 15, 2011

(30) Foreign Application Priority Data
Jul. 16, 2010 (JP) 2010-161298

(51) Int. Cl. H01L 21/223; C23C 16/50

(52) U.S. Cl. 438/513; 118/723 R; 257/E21.143

(57) ABSTRACT

A plasma doping apparatus for adding an impurity to a semiconductor substrate includes a chamber, a gas supply unit configured for supplying gas to the chamber, and a plasma source by which to cause the chamber to generate plasma of the supplied gas. The mixed gas containing material gas containing an impurity element to be added to the semiconductor substrate, hydrogen gas, and diluent gas for diluting the material gas is supplied to the chamber.

### BACKGROUND OF THE INVENTION

1. Field of the Invention

The present invention relates to a plasma doping apparatus and a plasma doping method.

2. Description of the Related Art

Attempts are being made to apply plasma doping techniques, in addition to ion implantation techniques, to the formation of an impurity-implanted layer on a substrate surface in a semiconductor fabrication process. There is much expectation placed on implantation of an impurity by plasma doping as a new practical method for realizing very shallow low-resistance junctions at high throughput.

For instance, an amorphous layer is formed by irradiating a silicon substrate surface with plasma and then an impurity is introduced into the amorphous layer. The impurity to be introduced is, for example, boron, and a diborane gas, for instance, is used as the material gas containing boron.

### SUMMARY OF THE INVENTION

One embodiment of the present invention provides a plasma doping apparatus for adding an impurity to a semiconductor substrate. The apparatus includes: a chamber; a gas supply unit configured to supply gas to the chamber; and a plasma source configured to cause the chamber to generate plasma of the supplied gas. The gas supply unit is structured such that a mixed gas containing (1) material gas containing an impurity element to be added to the semiconductor substrate, (2) hydrogen gas, and (3) diluent gas for diluting the material gas is supplied to the chamber.

Another embodiment of the present invention provides a plasma doping method in which a mixed gas containing material gas having an impurity element is supplied to an vacuum environment, plasma of the mixed gas is generated, and the impurity element is implanted by irradiating a substrate with the plasma in the vacuum environment. The method is such that hydrogen is mixed into the plasma whereby uneven distribution of density in an amorphous layer to be formed by a plasma irradiation on the surface of substrate is reduced.

### BRIEF DESCRIPTION OF THE DRAWINGS

Embodiments will now be described, by way of example only, with reference to the accompanying drawings, which are meant to be exemplary, not limiting, and wherein like elements are numbered alike in several figures, in which:

FIG. 1 is a schematic diagram showing a structure of a plasma doping apparatus according to an embodiment of the present invention;

FIG. 2 is a scatter diagram showing a relationship between the bias voltage and the surface roughness of a substrate subjected to typical plasma doping and annealing;

FIG. 3 is a diagram for explaining a generation mechanism of surface roughness by plasma doping;

FIG. 4 is a graph showing a measurement result of sheet resistance according to an embodiment of the present invention;

FIG. 5 is a graph showing a result of analysis, according to an embodiment of the present invention, using a secondary ion mass spectrometry;

FIG. 6 is a graph showing a measurement result of sheet resistance according to an embodiment of the present invention;

FIG. 7 are graphs showing measurement results of sheet resistance according to an embodiment of the present invention;

FIG. 8 are graphs showing measurement results of within-surface uniformity of sheet resistance according to an embodiment of the present invention;

FIG. 9 are graphs showing measurement results of sheet resistance according to an embodiment of the present invention; and

FIG. 10 are graphs showing measurement results of within-surface uniformity of sheet resistance according to an embodiment of the present invention.

### DETAILED DESCRIPTION OF THE INVENTION

The invention will now be described by reference to the preferred embodiments. This does not intend to limit the scope of the present invention, but to exemplify the invention.

An amorphous layer in an impurity implantation process works to suppress the channeling effect. That is, the amorphous layer formed before the implantation of an impurity can prevent the diffusion of the impurity into extra depths in the implantation process. The formation of the amorphous layer by plasma irradiation mentioned above uses the so-called bombardment effect to advantage. In other words, the amorphous layer is formed by creating crystal defects on the surface layer of substrate by collisions of a large amount of helium ions. And the implantation of an impurity is performed after the formation of this amorphous layer.

After the implantation of the impurity, a heat treatment is carried out to electrically activate the impurity. This process takes place in plasma doping in the same way as in an ordinary ion implantation. However, in the amorphous layer forming and doping with plasma using helium gas, there occurs uneven distribution of density in the amorphous layer. Because of this uneven distribution of density, defects can occur at the crystal regeneration by the heat treatment. And this results in a drop in the yield of the device which is fabricated as a final product and a decline in device performance. The fact is that, because of these problems, the impurity introduction methods as disclosed in the above-mentioned References in the Related Art List have not yet reached the stage of practical application.

It is therefore desirable to provide a plasma doping apparatus and a plasma doping method that can prevent the above-described occurrence of crystal defects and realize the formation of very shallow low-resistance junctions at high throughput.

One embodiment of the present invention provides a plasma doping apparatus for adding an impurity to a semiconductor substrate. This plasma doping apparatus includes a chamber, a gas supply unit for supplying gas to the chamber, and a plasma source for generating plasma in the gas supplied from the gas supply unit to the chamber. The gas supply unit is configured such that a mixed gas containing material gas containing an impurity element to be added to the semiconductor substrate, hydrogen gas, and diluent gas to dilute the material gas is supplied to the chamber.

By employing this embodiment, the mixing of hydrogen to the plasma enforces the self-recovery action of crystals in the surface layer of substrate against the ion collisions from the plasma. And this results in a mitigation of uneven distribution of density in the amorphous layer to be formed by plasma irradiation on the surface of substrate and suppressed growth of defects in the subsequent activation processes.

Another embodiment of the present invention provides a plasma doping method. In this method, a mixed gas containing material gas having an impurity element is supplied to an vacuum environment, plasma of the mixed gas is generated, and the impurity element is implanted by irradiating a substrate with the plasma in the vacuum environment. Also, this method is such that hydrogen is mixed into the plasma, thereby diminishing uneven distribution of density in the amorphous layer to be formed by the plasma irradiation on the surface of substrate.

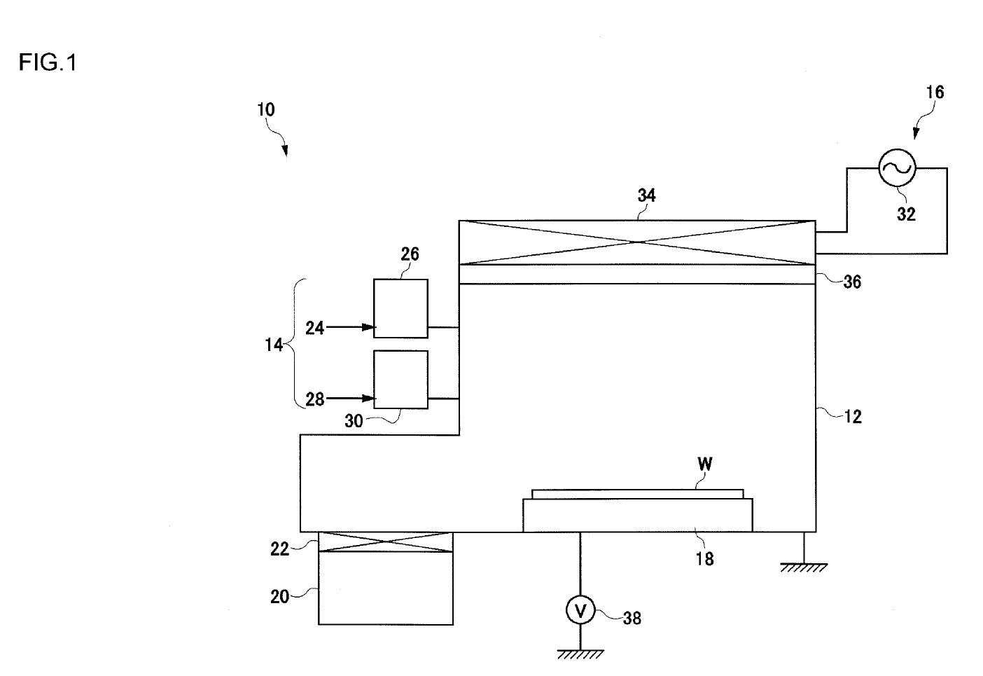

FIG. 1 is a schematic diagram showing a structure of a plasma doping apparatus 10 according to an embodiment of the present invention. The plasma doping apparatus 10 includes a chamber 12, a gas supply unit 14, a plasma source 16, and a substrate holder 18. The plasma doping apparatus 10 is provided with a control unit (not shown) which controls these constituent units and other units involved.

The chamber 12 is a vacuum container providing a vacuum environment inside. The chamber 12 has a vacuum pump 20 annexed thereto which evacuates the inside thereof. The vacuum pump 20 is a turbo-molecular pump, for instance. The vacuum pump 20 is connected to the chamber 12 by way of a vacuum valve 22. The vacuum valve 22, which is, for instance, a variable conductance valve, is attached to a suction inlet of the turbo-molecular pump. Provided subsequent to the turbo-molecular pump is a roughing pump (not shown). The chamber 12 is connected to ground.

The vacuum pump 20 and the vacuum valve 22 constitute an automatic pressure control (APC) system that controls the interior of the chamber 12 at a desired degree of vacuum. The automatic pressure control system further includes a pressure sensor (not shown) for measuring the pressure in the chamber 12 and a pressure controller (not shown) for controlling the vacuum valve 22 (and the vacuum pump 20) based on the pressure measurement. The automatic pressure control system maintains the vacuum environment inside the chamber 12 within a process gas pressure range desirable for plasma doping process, for instance.

The gas supply unit 14 is provided to supply process gas to the chamber 12. The gas supply unit 14 includes a single or a plurality of gas sources and a piping system leading the gas to the chamber 12 by connecting the gas source or sources thereto. The piping system includes a mass flow controller for controlling the flow rate of the gas to be supplied to the chamber 12. Where the gas supply unit 14 has a single gas source, the arrangement may be such that a process gas containing plural kinds of gas mixed beforehand in desired proportions is stored in the gas source.

In the illustrated exemplary embodiment, the gas supply unit 14 has an impurity gas source 24 and a carrier gas source 28. The gas supply unit 14 is provided with a first mass flow controller 26 to control the flow rate of an impurity gas supplied from the impurity gas source 24 and a second mass flow controller 30 to control the flow rate of a carrier gas supplied from the carrier gas source 28.

The impurity gas is a material gas containing a desired impurity to be added to a substrate W or a gas made by diluting the material gas with a diluent gas. The material gas is to be so selected as to meet the desired impurity. The molecules of the material gas contain the impurity element. When the impurity to be implanted in the substrate W is, for instance, boron (B), phosphorus (P) or arsenic (As), the material gas to be used is B₂H₆, PH₃ or AsH₃, for instance. In one exemplary embodiment, the impurity may be at least one of boron, phosphorus, arsenic, gallium, germanium, and carbon.

The diluent gas to dilute the material gas is, for instance, any of hydrogen, argon, helium, neon, and xenon. Or two or more of these gases may be used in combination as the diluent gas. The diluent gas may also be used as an assist gas to improve the ignitability of plasma in the material gas. In one exemplary embodiment, B₂H₆ gas, when it is used as the material gas, is diluted to 20% or below with hydrogen gas in order to avoid powderization of boron at the gas source. The carrier gas to be supplied from the carrier gas source 28 is, for instance, any of hydrogen, argon, helium, neon, and xenon as with the diluent gas. Also, two or more of these gases may be used in combination as the carrier gas.

The gas supply unit 14 supplies a mixed gas at a desired flow rate ratio to the chamber 12 by controlling the flow rate of the impurity gas with the first mass flow controller 26 and the flow rate of the carrier gas with the second mass flow controller 30. As will be discussed later, in one exemplary embodiment of the present invention, the mixed gas contains material gas, hydrogen gas, and diluent gas. Hence, the gas stored in at least one of the impurity gas source 24 and the carrier gas source 28 contains hydrogen gas. Or the gas supply unit 14 may have a hydrogen supply system for supplying hydrogen gas to the chamber 12. Thus, the gas supply unit 14 is so configured as to supply the mixed gas containing material gas, hydrogen gas, and diluent gas to the chamber 12.

The plasma source 16 generates plasma in the gas supplied from the gas supply unit 14, to the chamber 12. The plasma source 16 is installed in contact with the exterior of the chamber 12. In one exemplary embodiment, the plasma source 16 is a plasma source of ICP (inductively coupled plasma). The plasma source 16 includes a high-frequency power source 32, a plasma generating coil 34, and an insulator 36. The high-frequency power source 32, which is, for instance, an AC power source of 13.56 MHz, supplies the electric power to the plasma generating coil 34. The plasma generating coil 34 is attached to a surface (top surface in the illustration) of the chamber 12 opposite to the substrate holder 18. The surface of the chamber 12 to which the coil 34 is attached is provided with the insulator 36, which is a flange constructed of a dielectric material.

The substrate holder 18 is disposed inside the chamber 12 to hold the substrate W to which plasma doping is performed. The substrate W is a semiconductor substrate formed of silicon as the main material, for instance. The substrate holder 18 may be provided with an electrostatic chuck or other securing means in order to hold the substrate W. In one exemplary embodiment, the substrate holder 18 has a substrate contact member whose temperature is controlled, and the substrate W placed on the substrate contact member is secured by electrostatic adsorption. In this manner, the substrate W is controlled at a substrate temperature desirable for plasma doping.

Also connected to the substrate holder 18 is a bias power supply 38. The bias power supply 38 gives the substrate W, which is held to the substrate holder 18, a potential for pulling ions in the plasma toward it. The bias power supply 38 may be a DC power supply, a pulse power supply, or an AC power supply. In the illustrated exemplary embodiment, the bias power supply 38 is an AC power supply. In this case, the power supply used is an AC power supply of lower frequency (e.g., 1 MHz or below) than the high-frequency power source 32 for plasma generation. Accordingly, the bias power supply 38 may sometimes be referred to as “low-frequency power source” hereinbelow.

With the plasma doping apparatus 10, a plasma doping process is performed as described below, for instance. First, the chamber 12 is evacuated to a desired degree of vacuum by the vacuum pump 20, and a substrate W to be processed is introduced in the chamber 12. The substrate W is held by the substrate holder 18. A process gas mixed at a desired flow rate ratio is supplied to the chamber 12 by the operation of the gas supply unit 14. In this process, the degree of vacuum is controlled continuously by the APC system. Now a magnetic field is generated by energizing the plasma generating coil 34 from the high-frequency power source 32. The magnetic field generates plasma in the process gas by entering into the chamber 12 through the insulator 36.

A potential is produced in the substrate W, which is held by the substrate holder 18, by the use of the bias power supply 38. With ions present in the plasma accelerated toward the substrate W, an impurity is implanted in a surface layer region of the substrate W. When predetermined termination conditions are met, the power supply from both the high-frequency power source 32 and bias supply 38 is stopped. The gas supply is also stopped. The substrate W after the process is removed from the chamber 12.

Note that the supply of material gas to the chamber 12 may also be started after the ignition of plasma. In this case, the supply of carrier gas is started in advance, and the material gas is supplied to the chamber 12 after plasma is generated in the carrier gas. Also, at the termination of the plasma doping process, the arrangement may be such that the supply of material gas is stopped first, and then the plasma is extinguished by stopping the power supply and the carrier gas supply.

The substrate W after the plasma doping is subjected to a heat treatment, which is a post-plasma-doping process. This heat treatment is performed with the purpose of effecting recovery from the crystal defects produced on the substrate W by the plasma doping process and electrically activating the implanted impurity. The heat treatment, which is, for instance, rapid thermal annealing (RTA), laser anneal, or flashlamp anneal, is carried out by a not-shown anneal apparatus. In one exemplary embodiment, an in-line type substrate processing system may be configured, in which the substrate is processed continuously with the anneal apparatus connected as a post-process to the plasma doping apparatus. It is to be noted, however, that in the illustrated exemplary embodiment, the plasma doping apparatus is installed independently of the other processes as an off-line processing apparatus with which the substrate is carried in and out individually.

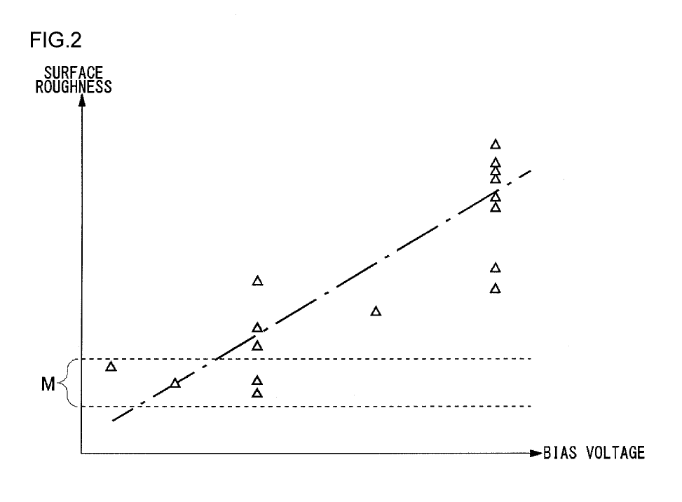

FIG. 2 is a scatter diagram showing a relationship between the bias voltage and the surface roughness of a substrate subjected to typical plasma doping and annealing. It represents the results of measurement by the inventors of the present invention. The measurements indicated by Δ (triangle) are the values of root-mean roughness within a 500 nm square near the center of a 300 mm silicon wafer as measured by an atom force microscope (AFM). The silicon wafer used in the measurement was subjected to a plasma doping with a B₂H₆ gas diluted to 1000 ppm by helium gas. The dosage was 1.5×10¹⁵ atoms/cm². The anneal conditions employed were nitrogen atmosphere, 1150° C., and 30 seconds. The dashed-dotted line in FIG. 2 represents the tendency of the measurement results.

A range M indicated by the dotted lines in FIG. 2 represents the root-mean roughness to be gained by the same dosage (1.5×10¹⁵ atoms/cm²) of known ion implantation of low energy (300 eV). Note that the present device fabrication is being conducted within this range M. Hence, it is to be considered that other techniques of impurity implantation have no problems so long as the root-mean roughness obtained stays within the range M.

As shown in FIG. 2, when the bias voltage in plasma doping is low, the substrate surface roughness after annealing is at about the same level as after a low-energy ion implantation. However, in plasma doping, it is evident that as the bias voltage rises, the substrate surface roughness after annealing tends to increase beyond that after the low-energy ion implantation. This is considered to be the result of the remaining crystal defects produced by the bombardment effect of a large amount of helium ions.

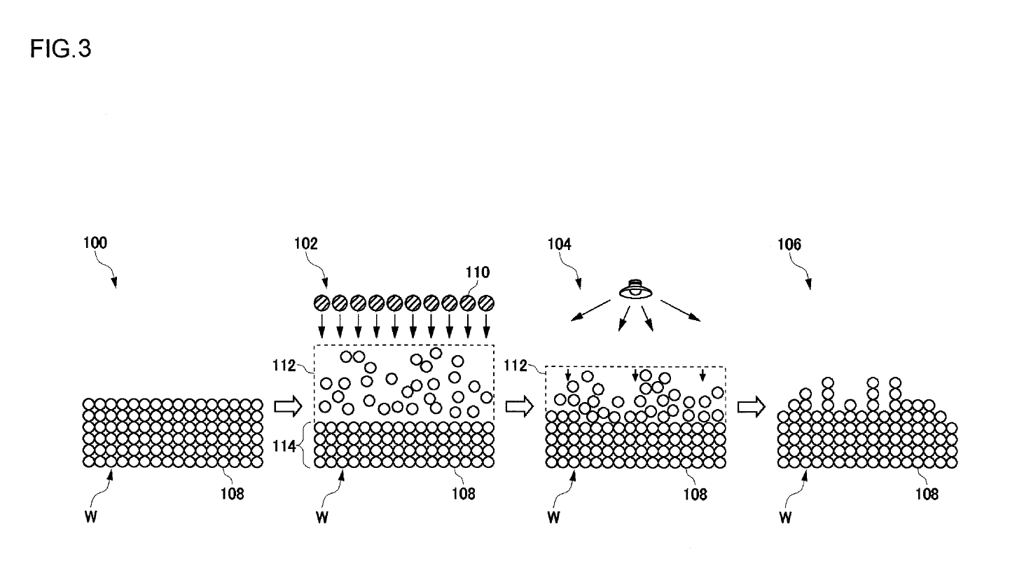

FIG. 3 is a diagram for explaining a generation mechanism of surface roughness by plasma doping. Shown in FIG. 3 is a surface roughness generation mechanism as understood by the inventors. Illustrated in FIG. 3 are an initial state 100 of a substrate W, a plasma doping process 102, an annealing process 104, and a roughened surface state 106 of the substrate W. In the initial state 100, atoms (e.g., silicon atoms) 108 constituting the substrate W are arranged in a crystalline state.

In the plasma doping process 102, a large amount of ions 110 are pulled and collide against the substrate surface. Where the material gas is diluted with helium gas as described previously, a large amount of helium ions from the plasma are accelerated toward the substrate W and collide with the substrate atoms 108. The substrate atoms 108 are scattered by the collision, and consequently an amorphous layer 112 (indicated by broken lines in FIG. 3) whose density is slightly lower than that of a crystalline layer 114 is formed on the surface of the substrate W. The density distribution in the amorphous layer 112 is not uniform. As shown in FIG. 3, the density distribution in the amorphous layer 112 is considered to have local irregularities.

The substrate W is subjected to the heating by the annealing process 104. In the initial phase of annealing, the substrate atoms 108 in the amorphous layer 112 are rearranged in the vertical direction, drawn by the original crystalline layer 114 which is present below the amorphous layer 112. The substrate atoms 108, once arranged vertically, do not easily move horizontally. Accordingly, the positions of the amorphous layer 112 where there are fewer substrate atoms 108 in the vertical direction form recesses whereas the positions thereof where there are more substrate atoms 108 in the vertical direction form projections. Thus, as shown by the roughened surface state 106, it is considered that the irregularities or uneven distribution of density in the amorphous layer 112 make their appearance as the asperity on the surface of the substrate, namely, the surface roughness of the substrate. It should be noted that the higher the bias voltage applied to the substrate, the larger the crystal defects that occur on the substrate surface will be.

Since the impurity is activated by an annealing process, the sheet resistance of the substrate surface drops lower than before the annealing process. Yet, as a result of the remaining defects on the substrate surface as shown in FIG. 3, the sheet resistance does not drop to a level to which it should normally drop, due to the activation of the impurity. This in turn can lead to a drop in operation speed of the device, which is a final product, and energy loss due to ohmic heating therein. In the worst case, where the defect coincides with the point of contact with the gate of the device, the device may not function at all. This may reduce the device yield when plasma doping is employed in the fabrication process. The narrower the circuit line width becomes with the progress of miniaturization, the graver the consequence of these defects will be.

The plasma doping has drawn attention as a substitute technique for ion implantation primarily because of its expected potential for relatively easy batch implantation of larger area at low energy and formation of shallow junctions at high throughput. Use of material gas diluted to an extremely low concentration with helium gas can achieve excellent uniformity and repeatability of the implantation amount of impurity because the sputtering and the injection of the impurity can be well balanced with each other. Since the diffusion of the implanted impurity stops at the boundary between the amorphous layer and the crystals, an excellent result can also be obtained as to the abruptness (steepness) of the dose profile which determines the performance of the semiconductor.

Thus, a technology to reduce the defects on the substrate surface after the process of activating the impurity is in demand in promoting the practical application of impurity implantation by plasma doping which has the aforementioned advantages. At present, however, there seems to be no understanding as to the nature of such a technology or even the necessity for such a suppression measure. For example, there is no mention at all in the above-cited documents as to the presence of roughness on the substrate surface after annealing that cannot be ignored.

As the defects mentioned above are attributable to a large amount of assist gas ions, a number of simple countermeasures may be conceivable. For example, such measures may include (1) use of an element of lighter atomic weight for assist gas, (2) reduction of implantation energy, and (3) reduction of the amount of assist gas. However, none of these measures necessarily provides realistic solutions. For example, the gas which has a lighter atomic weight than helium gas, which is considered relatively satisfactory as assist gas, is hydrogen only, and yet hydrogen gas, when used solely as assist gas, does not satisfy the uniformity, repeatability, and abruptness requirements from the viewpoint of practical application. Also, the implantation depth is determined by the desired performance of the device to be fabricated, which in turn determines the implantation energy to be used. Hence, the implantation energy is, in effect, not a parameter that is adjustable. Also, reduction of the amount of assist gas raises the concentration of material gas, thereby obviously deteriorating the uniformity, repeatability, and abruptness of dosage.

Under these circumstances, the inventors have conducted careful investigations and experiments with due diligence and have eventually discovered a method effective in suppressing the defects after the annealing while achieving the satisfactory uniformity, repeatability, and abruptness of dosage. The inventors have found that the mixing of a proper amount of hydrogen into the plasma can achieve the satisfactory uniformity, repeatability, and abruptness by mitigating the bombardment effect of colliding particles and thus reducing the uneven distribution of density in the amorphous layer.

The mixing of a proper amount of hydrogen into the plasma strengthens the self-recovery action of crystals in the surface layer of the substrate against the ion collisions from the plasma. That is, hydrogen radicalized or ionized by the plasma acts on the bond between the substrate atoms (e.g., silicon) broken by the bombardment of helium, instantaneously creating a bond between silicon and hydrogen. The binding force of this new bond, however, is weak, so that it is eventually broken by the bombardment of helium. Yet, the presence of this silicon-hydrogen bond creates a necessity for more energy to break the crystal than when hydrogen is not mixed in. For the same energy, therefore, there will be a lesser degree of destruction of crystals. And this results in a mitigation of uneven distribution of density in the amorphous layer to be formed by plasma irradiation on the surface of substrate and suppressed growth of defects in the subsequent activation processes.

In one exemplary embodiment of the present invention, a mixed gas containing (1) material gas containing a desired impurity element, (2) hydrogen gas, and (3) diluent gas for diluting the material gas is supplied to the chamber 12. This mixed gas may contain a material gas diluted to a low concentration, a hydrogen gas of a higher concentration than the material gas, and the rest which is practically the diluent gas. The diluent gas is, for instance, helium gas, which may be of a higher concentration than hydrogen gas. In one exemplary embodiment, the concentration of material gas is 1% or below. In one exemplary embodiment, the concentration of hydrogen gas is 1% or above.

In one exemplary embodiment, the plasma doping apparatus 10 may be of such an arrangement that an impurity material gas diluted to a low concentration of 1% or below by helium gas or other diluent gas is used and that hydrogen is mixed into plasma at the time of impurity implantation by plasma irradiation. Or, in another exemplary embodiment, the plasma doping apparatus 10 may be of such an arrangement that an impurity material gas diluted to a low concentration of 1% or below by hydrogen gas or other diluent gas is used and that helium is mixed into plasma at the time of impurity implantation by plasma irradiation.

In this manner, the concurrent presence of hydrogen and helium in the plasma can realize a concurrence of crystalline destruction by helium and crystalline recovery by hydrogen. Thus, the uneven distribution of density in the amorphous layer can be mitigated. One key point in determining a desirable concentration of hydrogen gas is a balance between the crystalline recovery by hydrogen gas and the bombardment effect by the diluent gas, and a desirable range for the concentration of the hydrogen gas can be determined through experiments.

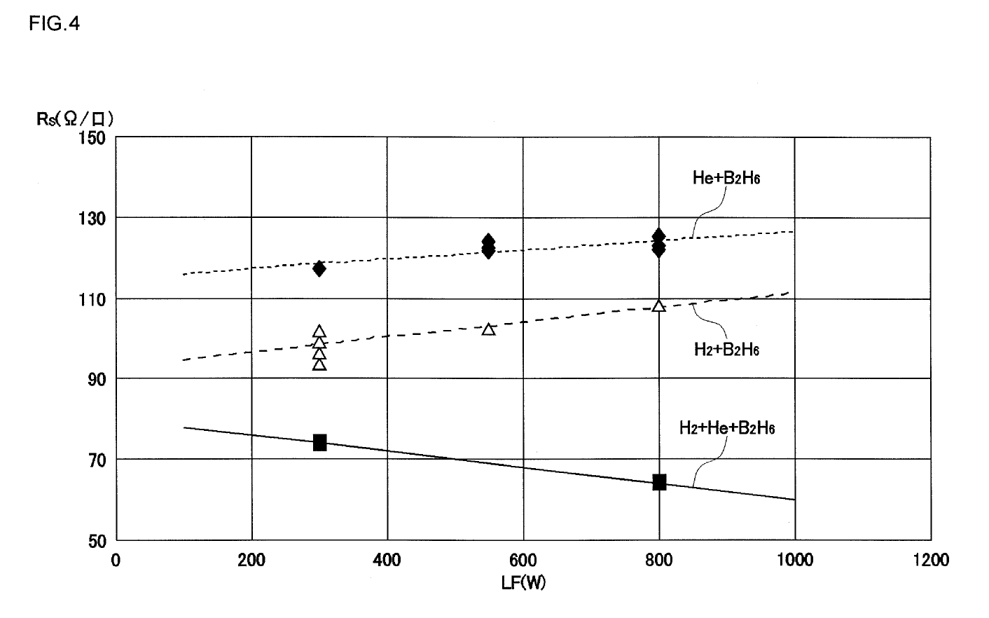

Referring to FIG. 4 to FIG. 6, measurement results by the plasma doping according to one embodiment of the present invention are explained. In this exemplary embodiment, the plasma doping apparatus 10 as shown in FIG. 1 performed plasma doping on the substrate, using the mixed gas wherein the flow rate ratio of hydrogen gas to the mixed gas is 7%, the flow rate ratio of B₂H₆ gas thereto is 0.2%, and the rest which is helium gas whose flow rate ratio is about 93%. The substrate used herein is a wafer, whose diameter is 300 mm, for an N type semiconductor. The dosage was 1.3×10¹⁵ atoms/cm². Then the annealing was done by the anneal apparatus at 1150° C. for 30 seconds.

Note that the annealing at 1150° C. for 30 seconds is an anneal sufficient to activate the implanted impurity. Empirically speaking, an anneal at 1050° C. or above and for 5 seconds or more can be evaluated to be sufficient for the activation of the implanted impurity. Thus, it is predicted that a similar satisfactory result will be obtained if the anneal at 1050° C. or above and for 5 seconds or more is done as a post-plasma-doping process.

FIG. 4 is a graph showing a measurement result of sheet resistance according to an embodiment of the present invention. A sheet resistance value Rs, which is given in units of Ohms per square, is measured using a four-terminal measurement method. The vertical axis in FIG. 4 indicates the measurement value Rs of sheet resistance, whereas the horizontal axis in FIG. 4 indicates the level of wattage for the low-frequency power source. The sheet resistance value obtained when the mixed gas of the above-described flow rate ratios and the anneal conditions were used is indicated by a black square in FIG. 4, and its tendency is indicated by the solid line. As comparative examples, the measurement value for which the diluent gas is helium gas only is indicated by a black diamond mark, whereas the measurement value for which the diluent gas is hydrogen gas only is indicated by Δ (triangle). These two comparative examples are processed and measured under the same conditions as those of the exemplary embodiment except for the diluent gas. The tendencies for the comparative examples are indicated by the dotted lines.

When the gas containing both helium and hydrogen is used, the sheet resistance value was dropped drastically as compared with when the gas containing either one of them only is used, while the dosage of the gas containing both helium and hydrogen and the dosage of the gas containing either one of them only are almost the same (namely, about 1.5×10¹⁵ atoms/cm²). This is quite a remarkable result. The sheet resistance measurement value in the present exemplary value is about 70 Ohms per square, as compared with the comparative example where the sheet resistance measurement value for which helium only is used is about 120 Ohms per square and the comparative example where the sheet resistance measurement value for which hydrogen only is used is about 100 Ohms per square. The sheet resistance value varies depending on a plasma doping condition and an anneal condition. However, the phenomenon that the sheet resistance value is small when hydrogen is mixed will remain intact even though the processing conditions vary. A reason why the comparative example where hydrogen only is used is smaller in the sheet resistance than the comparative example where helium only is used is that hydrogen has a lighter atomic weight than helium and therefore the bombardment effect is smaller.

According to the present exemplary embodiment, the sheet resistance values are kept at a low level over a wide range of implantation energies from a low energy of about 100 W to a high energy of about 1000 W. Note here that when a silicon substrate is used as the substrate, the depth from the substrate surface at which the impurity concentration at 100 W drops to 1.5×10¹⁸ atoms/cm² is about 2 nm and the depth therefrom at which the impurity concentration at 1000 W is about 18 nm. In the comparative examples, the sheet resistance tends to become larger as the implantation energy is raised. In the present exemplary embodiment, on the other hand, the sheet resistance drops as the implantation energy is raised. As shown in FIG. 2, in the typical plasma doping, the surface roughness after annealing becomes larger as the implantation energy is raised. In contrast thereto, in the present exemplary embodiment, it is estimated that even when a high energy is applied, the surface roughness will be the same level as or below that when a low energy is applied.

A self-recovery capability in hydrogen is contributable to the satisfactory results of the present exemplary embodiment. That is, it is considered that hydrogen is mixed into the plasma and therefore the scattering of silicon atoms as a result of the collision of helium ions is suppressed by this silicon-hydrogen bond. In the comparative example where helium only is used, the influence of the bombardment effect by a large amount of helium ions are obvious and evident. The collision energy of each helium ion is not very large even through it is a high energy of about 1000 W. The scattering of silicon atoms is suppressed by the bond energy of hydrogen atoms, so that the amorphous layer whose density is comparatively high as a whole is formed. As a result, it is considered that the sheet resistance and the surface roughness after the annealing have become lower in the present exemplary embodiment.

For similar reasons, it is conceivable that the diluent gas (e.g., argon, xenon, neon, etc.) may be used together with or in the place of helium. In other words, the larger the atomic weight is, the larger the bombardment effect will be. Yet, the mixing of hydrogen can reduce the bombardment effect, so that the diluent gas whose atomic weight is larger can be used.

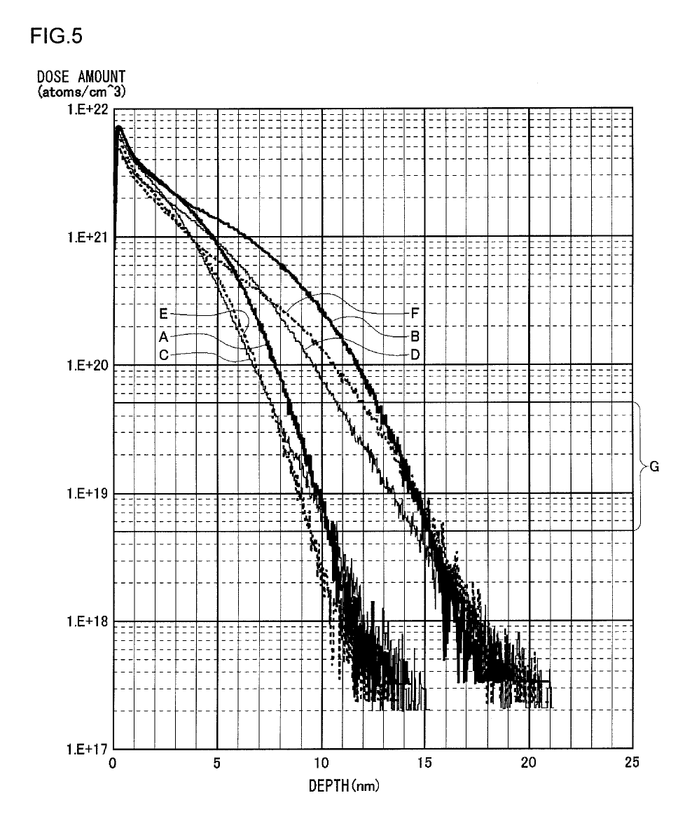

FIG. 5 is a graph showing a result of analysis, according to an embodiment of the present invention, using a secondary ion mass spectrometry (SIMS). Graph A to graph F shown in FIG. 5 are results of analysis in which the substrate is processed under the following conditions of gas composition, dosage, and common plasma doping and annealing except when the implantation energy is applied. The dosage of impurity is a dose amount equivalent in an SIMS analysis.

Graph A (exemplary embodiment): mixed gas, 1.28×10¹⁵ atoms/cm², 300 W.

Graph B (exemplary embodiment): mixed gas, 1.56×10¹⁵ atoms/cm², 800 W.

Graph C: diluent gas of hydrogen, 1.24×10¹⁵ atoms/cm², 300 W.

Graph D: diluent gas of hydrogen, 1.29×10¹⁵ atoms/cm², 800 W.

Graph E: diluent gas of helium, 1.13×10¹⁵ atoms/cm², 300 W.

Graph E: diluent gas of helium, 1.14×10¹⁵ atoms/cm², 800 W.

The mixed gas in graph A and graph B are such that the flow rate ratio of hydrogen gas to the mixed gas is 7%, the flow rate ratio of B₂H₆ gas thereto is 0.2%, and the rest which is helium gas whose flow rate ratio is about 93%. Graph C and graph D, as comparative examples, are such that B₂H₆ is diluted with hydrogen gas only. Graph E and graph F, as comparative examples, are such that B₂H₆ is diluted with helium gas only. Graph A, graph C and Graph E are cases where the implantation energy is low (300 W), whereas graph B, graph D and Graph F are cases where the implantation energy is high (800 W).

The result of SIMS analysis is used to identify the abruptness of the dose profile. Here, the difference between the depth from the substrate surface at which the dosage is 5×10¹⁹ atoms/cm³ is and the depth therefrom at which 5×10¹⁸ atoms/cm³ is defined to be an index representing the abruptness. In FIG. 5, the range of dosage from 5×10¹⁹ atoms/cm³ to 5×10¹⁸ atoms/cm³ is denoted by a range G. The depth change rate in this range G indicates the abruptness. The smaller the value of this depth change rate is, more satisfactory the abruptness will be.

Thus, the abruptness obtained from the result of SIMS analysis shown in FIG. 5 is as flows.

Graph A (exemplary embodiment, low energy): 1.9 nm.

Graph B (exemplary embodiment, high energy): 2.5 nm.

Graph C (diluted with hydrogen, low energy): 2.7 nm.

Graph D (diluted with hydrogen, high energy): 3.9 nm.

Graph E (diluted with helium, low energy): 1.9 nm.

Graph F (diluted with helium, high energy): 3.4 nm.

When diluted with hydrogen gas only, the abruptness deteriorates. The reason for the deteriorated abruptness when diluted with hydrogen gas only is assumed to be due to the fact that the thickness of the amorphous layer is extremely thin. The impurity is doped to a depth beyond the amorphous layer and therefore the amorphous layer does not function as a stopper layer for diffusion. In contrast to this, by employing the present exemplary embodiment or when diluted with helium, the amorphous layer is thicker and deeper than the case when diluted with hydrogen, so that the excellent abruptness is achieved.

It is found that the drop in the abruptness in the present exemplary embodiment is minimum though the abruptness in the case of a high energy applied is lower than that in the case of a low energy applied. It is also considered here that the crystalline self-recovery function by hydrogen accounts for these results.

The range G to define the abruptness is equivalent to expressing the thickness of the impurity layer. Thus, as shown in FIG. 5, the plasma doping method according to the present exemplary embodiment is suitable for forming an impurity layer, whose thickness is within about 10 nm, in the substrate in the case of a low energy applied. Also, the plasma doping method according to the present exemplary embodiment is suitable for forming an impurity layer, whose thickness is within about 15 nm, in the substrate in the case of a high energy applied. The plasma doping method according to the present exemplary embodiment adjusts the processing conditions and is suitable for forming an impurity layer, whose thickness is within about 30 nm, in the substrate.

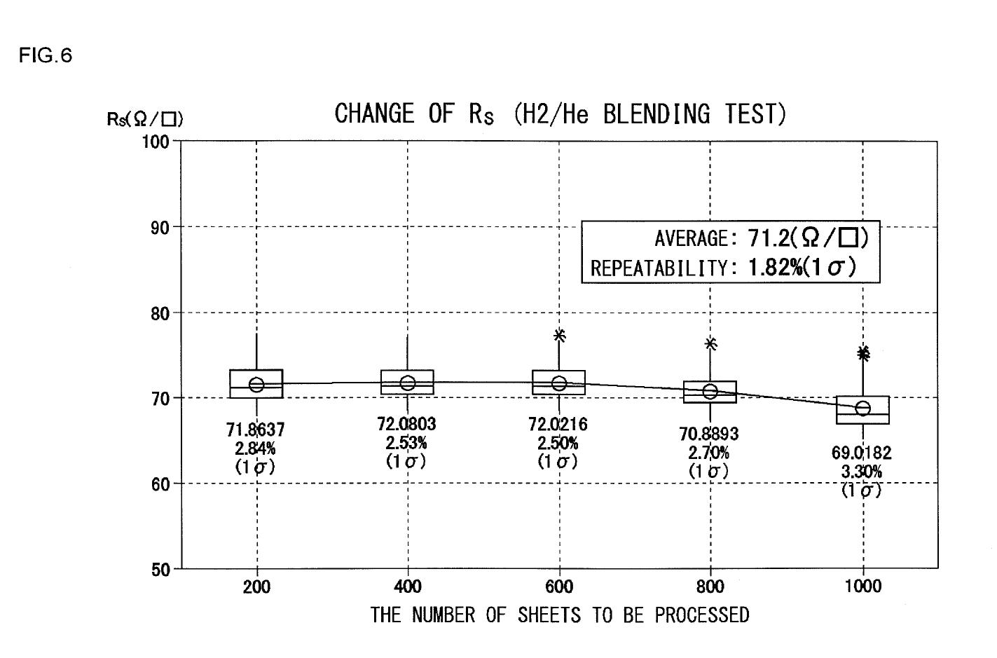

FIG. 6 is a graph showing a measurement result of sheet resistance according to an embodiment of the present invention. FIG. 6 shows the uniformity and repeatability of sheet resistance value Rs (Ohms per square) when plural sheets of wafers are processed using the mixed gas according to the present exemplary embodiment. The within-wafer uniformity and the repeatability, when 1000 sheets of wafers are processed, are an average of 2.8% (1σ) and 1.8% (1σ), respectively, which are excellent results. The same excellent uniformity and repeatability as those obtained when the material gas diluted to a low concentration by helium gas only is used can be obtained even if hydrogen is mixed as in the present exemplary embodiment.

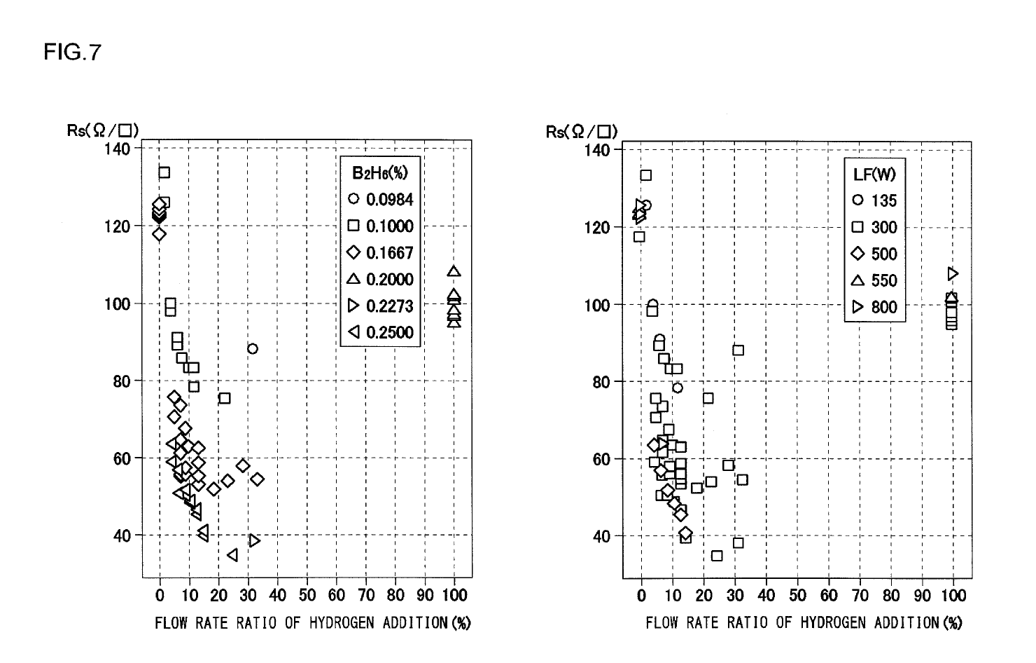

FIG. 7 are graphs showing measurement results of sheet resistance according to an embodiment of the present invention. Similar to the measurement result shown in FIG. 4, the sheet resistance value Rs (Ohms per square) is measured for a sample which is subjected to plasma doping of boron and annealing. Each point plotted on FIG. 7 indicates an average sheet resistance value of the whole surface of one sheet of substrate. The vertical axis in FIG. 7 indicates the measurement value Rs of sheet resistance. The horizontal axis in FIG. 7 indicates the flow rate ratio of hydrogen gas over the total flow of the mixed gas supplied for plasma doping. The measurement results of FIG. 7 are obtained when tests are conducted in a range from a micro amount (e.g., 1%) to about 30% of hydrogen mixed and when comparative examples are tested for non-helium content (the mixed gas of hydrogen gas and impurity gas only, namely, the flow rate ratio of hydrogen gas being 100%).

One on the left in FIG. 7 is a graph showing a case where the flow rate ratio of B₂H₆ gas is varied. The flow rate ratio of B₂H₆ gas is varied in a range from about 0.1% to about 0.3%. One on the right in FIG. 7 is a graph showing a case where an output LF of the bias power supply 38 is varied in a range from 135 W to 800 W. The plasma doping conditions common to each measurement result were (i) the power of the high-frequency power source 32 for plasma generation is 1500 W, (ii) the gas pressure during processing is 0.7 Pa, and (iii) the total flow of the mixed gas is 300 sccm. The rest of the mixed gas except for hydrogen gas and B₂H₆ gas is helium gas. The anneal conditions employed were the oxygen addition rate of 1%, a preset temperature of 1150° C., and the processing time of 30 seconds.

As shown in the left graph of FIG. 7, it is evident that in a test range up to about 30% of the flow rate ratio of hydrogen gas with a fixed flow rate ratio of B₂H₆ gas, the sheet resistance value starts to decline drastically after the mixing of a micro amount (e.g., 1%) of hydrogen gas and the sheet resistance value tends to drop steadily to the minimum level with the mixing of additional hydrogen gas. For example, in the points plotted on FIG. 7, which are denoted by “square” marks, indicating the flow rate ratio of B₂H₆ gas at 0.1%, the sheet resistance value reaches a minimum level at the flow rate ratio of hydrogen gas at about 12%. In this test range, an increase in the sheet resistance value with the flow rate ratio of hydrogen at about 100% was not observed. It is predicted that the sheet resistance value may increase in a range from a certain flow rate ratio of hydrogen beyond this test range toward the flow rate ratio of hydrogen at about 100%.

As described above, the sheet resistance value is an index to show the degree of roughness of the surface of substrate after annealing and is also an index to show the crystalline recovery as a result of the mixing of hydrogen gas. The smaller the sheet resistance value is, the smaller the roughness of the surface thereof will be. Thus, the measurement results shown in FIG. 7 indicate that a desirable range of the flow rate ratio of hydrogen for plasma doping is about 30% or below if the crystalline recovery by hydrogen gas is to be emphasized. The composition of process gas for plasma doping may be such that the flow rate ratio of B₂H₆ gas over the total flow is in a range of about 0.1% to about 0.3% and the flow rate ratio of hydrogen gas over the total flow is about 30% or below.

It is also found that the falling tendency of sheet resistance toward a minimum point shows some variation depending on the flow rate ratio of B₂H₆ gas. The larger the flow rate ratio of B₂H₆ gas is, the larger the flow rate ratio of hydrogen, where the sheet resistance value reaches the minimum point, becomes. The point at which the sheet resistance value reaches the minimum point is regarded as an optimum value of the flow rate ratio of hydrogen gas. As described above, the optimum value of the flow rate ratio of hydrogen is about 12% when the flow rate ratio of B₂H₆ gas is 0.1%. Also, when the flow rate ratio of B₂H₆ gas is 0.1667%, the optimum value of the flow rate ratio of hydrogen is about 15%. When the flow rate ratio of B₂H₆ gas is 0.25%, the optimum value of the flow rate ratio of hydrogen gas is about 20%.

Thus, in one exemplary embodiment, the flow rate ratio of hydrogen gas may be selected according to the flow rate ratio of an impurity gas (e.g., B₂H₆ gas). It is desirable that the larger the flow rate ratio of an impurity gas is, the larger the flow rate ratio of hydrogen gas becomes. Thus, for example, the range of flow rate ratio of an impurity gas to be used (e.g., a range from about 0.1% to about 0.3%) is divided into a plurality of widths (e.g., each divided width representing 0.05%). In this case, for a region where the flow rate ratio of an impurity gas is larger, a larger value is set to the flow rate ratio of hydrogen gas. In this manner, a flow rate ratio of hydrogen gas where the crystalline recovery is emphasized can be selected. This proves effective in cases where it is important to have a minimum sheet resistance value (surface roughness) in the devices which are the final products.

As shown in the right graph of FIG. 7, no significant difference in the tendency of the optimum value of the flow rate ratio of hydrogen gas is observed even when the level of wattage LF of the bias power supply 38 varies. Hence, it is considered that there is no effect of the bias voltage, applied to the substrate for plasma doping, on the optimum value of the flow rate ratio of hydrogen gas.

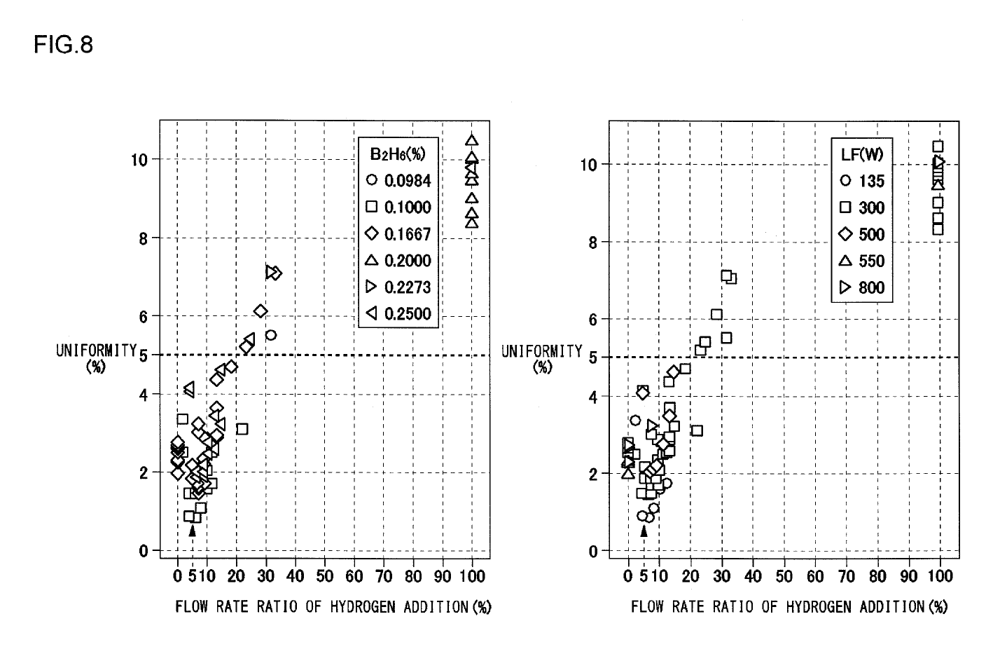

FIG. 8 are graphs showing measurement results of within-surface uniformity of sheet resistance according to an embodiment of the present invention. It is to be noted here the term “within-surface uniformity” and “within-wafer uniformity” are used interchangeably in this patent specification. The measurement results shown in FIG. 8 serve to evaluate the within-surface uniformity (1σ) of the sheet resistance for the substrate used in the measurement of FIG. 7. The vertical axis in FIG. 8 indicates the within-surface uniformity of sheet resistance value Rs. The horizontal axis in FIG. 8 indicates the flow rate ratio of hydrogen gas over the total flow of the mixed gas supplied for plasma doping. One on the left in FIG. 8 is a graph showing a case where the flow rate ratio of B₂H₆ gas is varied. One on the right in FIG. 8 is a graph showing a case where an output LF of the bias power supply 38 is varied in a range from 135 W to 800 W.

As shown in the left graph of FIG. 8, no significant difference in the tendency of the optimum value of the flow rate ratio of hydrogen gas is observed even when the flow rate ratio of the impurity gas varies. Also, as shown in the right graph of FIG. 8, no significant difference in the tendency of the optimum value of the flow rate ratio of hydrogen gas is observed even when the level of wattage LF of the bias power supply 38 varies. As for the uniformity, it is evident that the optimum flow rate ratio of hydrogen gas is about 5% regardless of the flow rate ratio of the impurity gas and the bias voltage.

According to knowledge gained by the inventors of the present invention, when the uniformity is within 5%, there is practically no effect of such uniformity on the yield of the devices produced. According to FIG. 8, the range of the flow rate ratio of hydrogen gas for which the uniformity becomes 5% or below is about 20% or below. Thus, where the uniformity of processing is emphasized, a desirable range of the flow rate ratio of hydrogen gas for plasma doping is about 20% or below. The flow rate ratio of B₂H₆ gas over the total flow of process gas for plasma doping may be in a range of about 0.1% to about 0.3%, and the flow rate ratio of hydrogen gas over the total flow thereof may be about 20% or below.

According to FIG. 8, the uniformity is about 4% or below, which is at a lower level, at a stage when a micro amount (e.g., 1%) of hydrogen gas was mixed. As the flow rate ratio of hydrogen exceeds about 10%, the uniformity also exceeds such a level. Thus, the flow rate ratio of hydrogen gas for plasma doping may be about 10% or below. The flow rate ratio of B₂H₆ gas over the total flow of process gas for plasma doping may be in a range of about 0.1% to about 0.3%, and the flow rate ratio of hydrogen gas over the total flow thereof may also be about 10% or below.

Where the uniformity is emphasized, the range of the flow rate ratios of hydrogen gas may be about 3% to about 5%. Thus, the flow rate ratio of B₂H₆ gas over the total flow of process gas for plasma doping may be in a range of about 0.1% to about 0.3%, and the flow rate ratio of hydrogen gas over the total flow thereof may be in a range of about 3% to about 5%. In this manner, the flow rate ratio of hydrogen gas with the uniformity emphasized can be selected. This proves effective in cases where it is important to enhance the uniformity in the devices which are the final products.

Since hydrogen gas is a flammable gas, it must be handled with care. To be disposed of after the plasma doping, the gas to be disposed of is desirably stored in such a manner that it can be diluted with diluent gas (e.g., nitrogen gas) to a concentration lower than an explosion limit (e.g., 4% in volume). Thus, in view of work burden and cost incurred in dilution as described above, the flow rate ratio of hydrogen may be as small as possible. If the flow rate ratio of hydrogen for plasma doping is below the explosion limit (e.g., 4%), no more extra dilution will be needed in the disposal of gas after the plasma doping. Thus, for the ease of handling of gas, the flow rate ratio of hydrogen gas for plasma doping may be 4% or below.

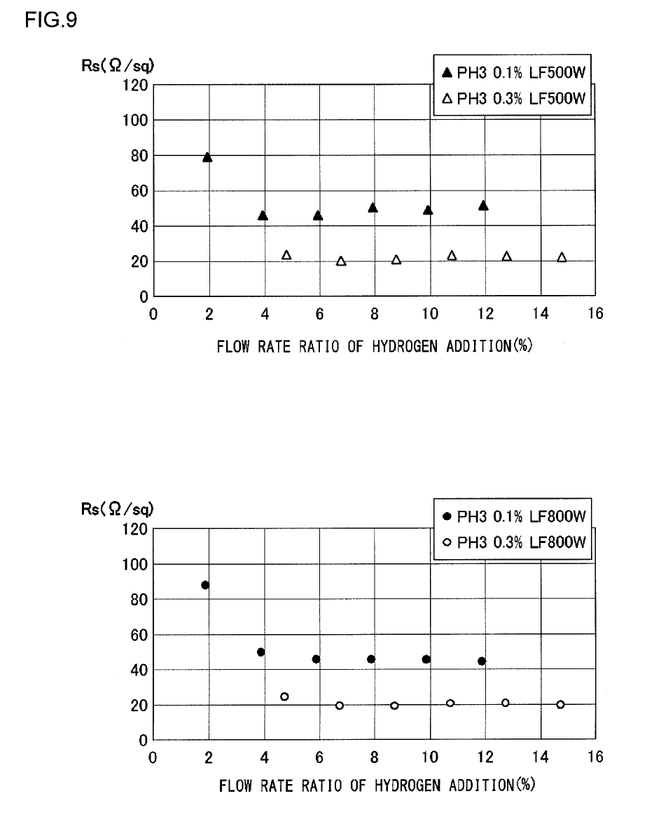

FIG. 9 are graphs showing measurement results of sheet resistance according to an embodiment of the present invention. Unlike FIG. 7, FIG. 9 shows the plasma doping of phosphorus using PH₃ gas. The test range of the flow rate ratio of hydrogen gas is up to about 15%. The other processing conditions are the same as those of FIG. 7. The upper graph in FIG. 9 shows a case where the bias output LF is 500 W, whereas the lower graph in FIG. 9 shows a case where the bias output LF is 800 W. Measurements in the cases where the flow rate ratios of PH₂ gas are 0.1% and 0.3% are recorded in each of the upper and lower graphs in FIG. 9.

Similarly, the measurement results shown in FIG. 9 indicate that a desirable range of the flow rate ratio of hydrogen for plasma doping is about 10% or below if the crystalline recovery by hydrogen gas is to be emphasized. The flow rate ratio of PH₃ gas over the total flow of process gas for plasma doping may be in a range of about 0.1% to about 0.3%, and the flow rate ratio of hydrogen gas over the total flow thereof may be about 10% or below.

Similarly to the case of boron, in the case of phosphorus, the larger the flow rate ratio of the impurity gas is, the larger the flow rate ratio of hydrogen, where the sheet resistance value reaches the minimum point, becomes. The optimum value of the flow rate ratio of hydrogen is about 4% when the flow rate ratio of PH₃ gas is 0.1%. When the flow rate ratio of PH₃ gas is 0.3%, the optimum value of the flow rate ratio of hydrogen is about 7%. The same tendency is expected to apply to phosphorus.

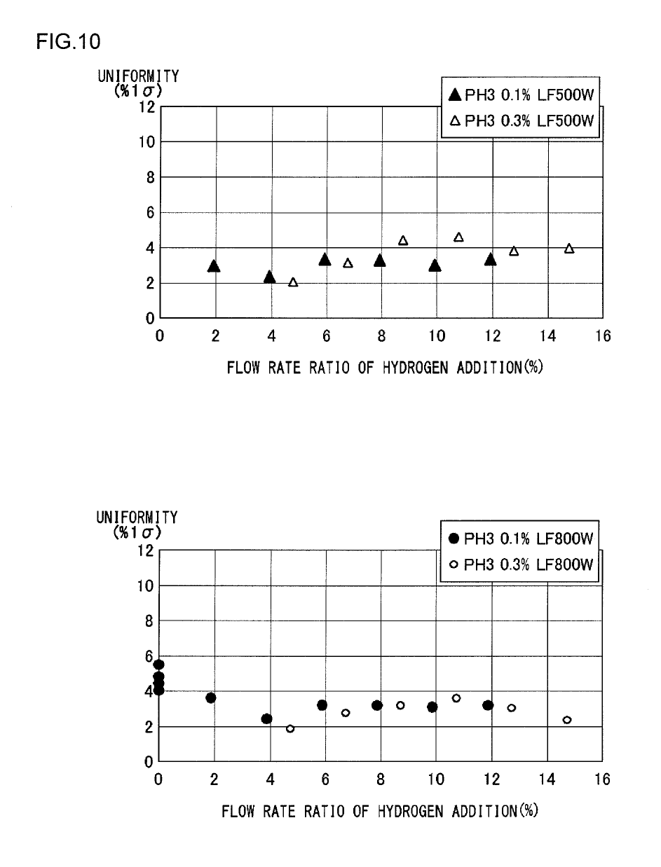

FIG. 10 are graphs showing measurement results of within-surface uniformity in sheet resistance according to an embodiment of the present invention. The measurement results shown in FIG. 10 serve to evaluate the within-surface uniformity (1σ) of the sheet resistance for the substrate used in the measurement of FIG. 9. Similarly to the case of boron shown in FIG. 8, it is evident that the optimum flow rate ratio of hydrogen gas is about 5% regardless of the flow rate ratio of the impurity gas and the bias voltage, when the uniformity of processing is emphasized. The optimum value of the flow rate ratio of hydrogen gas with the uniformity emphasized is considered to be independent of the impurity element implanted. Thus, boron and phosphorus share the same desirable range of the flow rate ratio of hydrogen gas with the uniformity emphasized. For example, the flow rate ratio of PH₃ gas over the total flow of process gas for plasma doping may be in a range of about 0.1% to about 0.3%, and the flow rate ratio of hydrogen gas over the total flow thereof may be in a range of about 3% to about 5%. The same desirable range of the flow rate ratio of hydrogen gas is expected to apply to phosphorus.

It should be understood that the invention is not limited to the above-described embodiments, but may be modified into various forms on the basis of the spirit of the invention. Additionally, the modifications are included in the scope of the invention.

Priority is claimed to Japanese Patent Application No. 2010-161298, filed Jul. 16, 2010, the entire content of which is incorporated herein by reference.

What is claimed is:

1. A plasma doping apparatus for adding an impurity to a semiconductor substrate, the apparatus comprising:
a chamber;
a gas supply unit configured to supply gas to the chamber; and
a plasma source that generates plasma in the gas supplied from the gas supply unit, to the chamber,
wherein the gas supply unit is configured such that a mixed gas containing (1) material gas containing an impurity element to be added to the semiconductor substrate, (2) hydrogen gas, and (3) diluent gas for diluting the material gas is supplied to the chamber.

2. The plasma doping apparatus according to claim 1, wherein the mixed gas contains the material gas diluted to a low concentration, the hydrogen gas of a higher concentration than the material gas, and the rest which is practically the diluents gas.

3. The plasma doping apparatus according to claim 2, wherein the diluents gas is helium gas which is of a higher concentration than the hydrogen gas.

4. The plasma doping apparatus according to claim 1, wherein the flow rate ratio of the hydrogen gas to the mixed gas is less than or equal to 20%.

5. The plasma doping apparatus according to claim 1, wherein the flow rate ratio of the hydrogen gas to the mixed gas is in a range of 3% to 5%.

6. A plasma doping method in which a mixed gas containing material gas having an impurity element is supplied to an vacuum environment, plasma of the mixed gas is generated, and the impurity element is implanted by irradiating a substrate with the plasma in the vacuum environment, wherein hydrogen is mixed into the plasma whereby uneven distribution of density in an amorphous layer to be formed by a plasma irradiation on the surface of substrate is reduced.
